(19) United States
(12) Patent Application Publication
(10) Pub. No.: US 2025/0006727 A1
(43) Pub. Date: Jan. 2, 2025

(54) IGBT, Method of Operating an RC IGBT, and a Circuit Including an IGBT

(71) Applicant: Infineon Technologies AG, Neubiberg (DE)

(72) Inventors: Frank Pfirsch, Munchen (DE); Roman Baburske, Otterfing (DE)

(21) Appl. No.: 18/753,518

(22) Filed: Jun. 25, 2024

(30) Foreign Application Priority Data
Jun. 27, 2023 (DE) 102023206027.2

(51) Int. Cl. H01L 27/06; H01L 29/06; H01L 29/08; H01L 29/10; H01L 29/739; H01L 29/861; H03K 17/567

(52) U.S. Cl. CPC H01L 27/0664; H01L 29/0638; H01L 29/0804; H01L 29/0834; H01L 29/1095; H01L 29/7397; H01L 29/8613; H03K 17/567

(57) ABSTRACT

An IGBT includes, in a single chip, an active region configured to conduct a forward load current between first and second load terminals at different sides of a semiconductor body. The active region is separated into at least first and second IGBT regions. At least 90% of the first IGBT region is configured to conduct, based on a first control signal, the forward load current. At least 90% of the second IGBT region is configured to conduct, based on a second control signal, the forward load current. A first MOS-channel-conductivity-to-area-ratio is determined by a total channel width in the first IGBT region divided by a total lateral area of first IGBT region. A second MOS-channel-conductivity-to-area-ratio is determined by a total channel width in the second IGBT region divided by a total lateral area of the second IGBT region. The second MOS-channel-conductivity-to-area-ratio amounts to less than 80% of the first MOS-channel-conductivity-to-area-ratio.

### TECHNICAL FIELD

This specification refers to embodiments of an IGBT, to embodiments of operating an IGBT, and to embodiments of a circuit comprising an IGBT.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a forward blocking state.

Furthermore, some devices provide for reverse load current capability. There, the active region of the semiconductor body is further configured to conduct a reverse load current along a reverse load current path between the two load terminals of the device. For example, the RC (Reverse Current) IGBT is one representative of such devices. In an RC IGBT, a single chip accommodates an IGBT structure and a diode structure. In comparison to a diode and an IGBT on separate chips that are connected anti-parallel to each other, the RC IGBT exhibits some advantages, e.g., in terms turn-on losses, reverse recovery losses and/or thermal behavior, but may also be more complex in control.

Furthermore, to influence the switching behavior of a transistor more accurately, two control signals or more than two control signals may be provided to control the transistor. For example, a dual gate IGBT (or a dual gate RC IGBT) is controlled based on two control signals.

### SUMMARY

The subject-matter of the independent claims is presented. Features of exemplary embodiments are defined in the dependent claims.

According to a first embodiment, an IGBT comprises, in a single chip, an active region configured to conduct a forward load current between a first load terminal at a front side of a semiconductor body of the IGBT and a second load terminal at a back side of the semiconductor body. The active region is separated into at least: a first IGBT region, at least 90% of which being configured to conduct, based on a first control signal, the forward load current; a second IGBT region, at least 90% of which being configured to conduct, based on a second control signal, the forward load current. A first MOS-channel-conductivity-to-area-ratio is determined by a total channel width in the first IGBT region divided by a total lateral area of first IGBT region. A second MOS-channel-conductivity-to-area-ratio is determined by a total channel width in the second IGBT region divided by a total lateral area of the second IGBT region. The second MOS-channel-conductivity-to-area-ratio amounts to less than 80% of the first MOS-channel-conductivity-to-area-ratio.

According to a second embodiment, an IGBT comprises, in a single chip, an active region configured to conduct a forward load current between a first load terminal at a front side of a semiconductor body of the IGBT and a second load terminal at a back side of the semiconductor body. The active region is separated into at least: a first IGBT region including first MOS-channels exhibiting a first threshold voltage, wherein at least 90% of the first IGBT region is configured to conduct, based on a first control signal, the forward load current; and a second IGBT region including second MOS-channels exhibiting a second threshold voltage amounting to at least 115% of the first threshold voltage, wherein at least 90% of the second IGBT region is configured to conduct, based on a second control signal, the forward load current.

According to a further embodiment, a method of operating an IGBT according to the first embodiment or according to the second embodiment is presented. The method comprises: controlling the first IGBT region based on the first control signal; and controlling the second IGBT region based on the second control signal.

According to a yet further embodiment, a circuit is presented. The circuit comprises an IGBT according to the first embodiment or according to the second embodiment; and a MOSFET connected in parallel to the IGBT.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a horizontal projection of an IGBT in accordance with one or more embodiments;

FIG. 2 schematically and exemplarily illustrates a section of a horizontal projection of an active region of an IGBT in accordance with one or more embodiments;

FIG. 3 schematically and exemplarily illustrates a section of a vertical cross-section of an IGBT in accordance with one or more embodiments;

FIG. 4 schematically and exemplarily illustrates a section of a vertical cross-section of a second IGBT region of an IGBT in accordance with one or more embodiments;

FIG. 5 schematically and exemplarily illustrates a section of a vertical cross-section of a first IGBT region of an IGBT in accordance with one or more embodiments;

FIG. 6 schematically and exemplarily illustrates two variants of a section of a perspective projection of a second IGBT region of an IGBT in accordance with one or more embodiments;

FIG. 7 schematically illustrates some examples of a method of operating an IGBT in accordance with one or more embodiments; and

FIG. 8 schematically and exemplarily illustrates transfer characteristics of a first IGBT region and a second IGBT region of an IGBT in accordance with one or more embodiments;

FIG. 9 schematically and exemplarily illustrates output characteristics of a first IGBT region and a second IGBT region of an IGBT during a turn-OFF operation in accordance with one or more embodiments; and

FIG. 10 schematically and exemplarily illustrates a circuit in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, an IGBT, e.g., a power semiconductor device that may be used within a power converter or a power supply. Thus, in an embodiment, such IGBT can be configured to carry a load current that is to be fed to a load and/or, respectively, that is provided by a power source. For example, the IGBT may comprise one or more active power semiconductor unit cells, such as a monolithically integrated diode cell, a derivative of a monolithically integrated diode cell, a monolithically integrated transistor cell, e.g., a monolithically integrated IGBT cell and/or derivatives thereof. Such diode/transistor cells may be integrated in a power semiconductor module. A plurality of such cells may constitute a cell field that is arranged within an active region of the power semiconductor device.

The term “blocking state” of the IGBT may refer to conditions, when RC IGBT is in a state configured for blocking a load current flow while an external voltage is applied. More particularly, the IGBT may be configured for blocking a forward load current through the RC IGBT while a forward voltage bias is applied. In comparison, the IGBT may be configured for conducting the forward load current in a “conducting state” of the IGBT while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the IGBT. The term “forward biased blocking state” therefore may refer to conditions with the IGBT being in the blocking state while a forward voltage bias is applied.

The term “IGBT” as used in this specification intends to describe an IGBT on a single chip with high voltage blocking and/or high current-carrying capabilities. In other words, such IGBT is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “IGBT” as used in this specification is not directed to logic semiconductor devices that are used for, e.g., storing data, computing data and/or other types of semiconductor-based data processing.

For example, the IGBT described below may be a single semiconductor chip, e.g., exhibiting a stripe cell configuration (or a cellular/needle cell configuration) and can be configured to be employed as a power component in a low-, medium- and/or high voltage application.

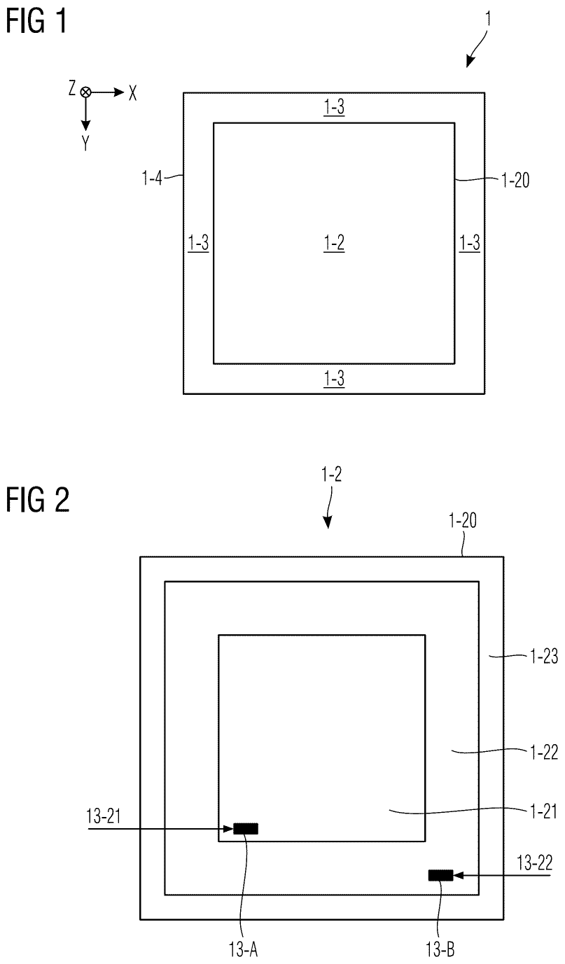

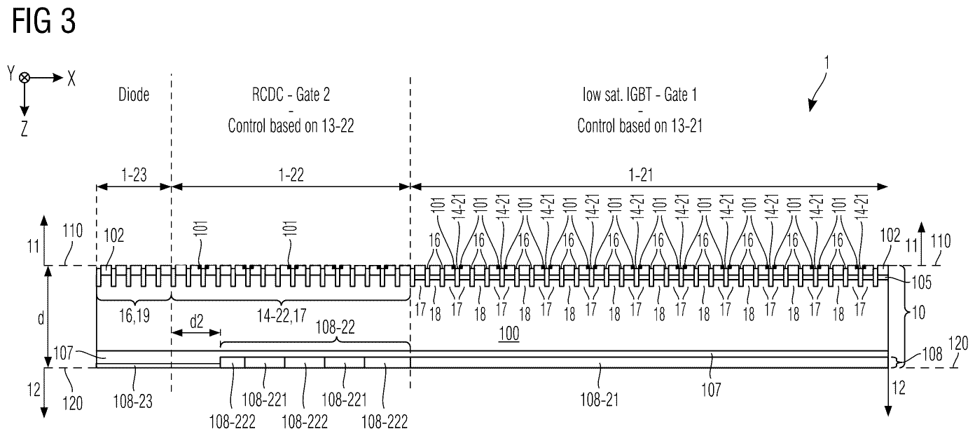

FIG. 1 schematically and exemplarily illustrates a section of a horizontal projection of an IGBT 1 in accordance with one or more embodiments. The exemplary vertical cross-section illustrated in FIG. 3 as well as the more detailed illustration of an exemplary active region 1-2 according to FIG. 2 are additionally referred to in the following.

The IGBT 1 comprises a semiconductor body 10 coupled to a first load terminal at a front side (also referred to as first side) 110 and to a second load terminal 12 at a back side (also referred to as second side) 120 that is opposite to the front side 110 with respect to the vertical direction Z. The semiconductor body 10 is part of a single chip that comprises an active region 1-2 configured to conduct a forward load current between the first load terminal 11 and the second load terminal 12. In an embodiment, the IGBT 1 may be configured as an RC IGBT; in this case, the active region 1-2 is configured to conduct both the forward load current and a reverse load current between the first load terminal 11 and the second load terminal 12.

The vertical thickness d of the semiconductor body 10 may be defined as the distance between the front side 110 and the back side 120 along the vertical direction Z, e.g., measured at a horizontal center of the active region 1-2.

The IGBT 1 may exhibit a vertical configuration according to which both the forward load current (and, optionally, in case of said RC IGBT configuration, the reverse load current) flow substantially in parallel to the vertical direction Z.

For example, the first load terminal 11 may be a source (or emitter) terminal, and the second load terminal 12 a drain (collector) terminal.

The active region 1-2 is surrounded by an edge termination region 1-3 which is terminated by a chip edge 1-4. Herein, the terms “active region” (sometimes also referred to as “cell field”), “edge termination region” and “chip edge” have the technical meanings the skilled person typically associates therewith in the context of IGBTs and are hence not explained in further detail.

According to the embodiments disclosed herein, the active region 1-2 of the IGBT 1 is separated into at least a first IGBT region 1-21 and a second IGBT region 1-22.

For example, at least 90% of the first IGBT region 1-21 is configured to conduct, based on a first control signal 13-21, the forward load current. Said share can be even greater than 90%, e.g., at least 95%, at least 98% or even amount to 100%.

For example, at least 90% of the second IGBT region 1-22 is configured to conduct, based on a second control signal 13-22, the forward load current. Said share can be even greater than 90%, e.g., at least 95%, at least 98% or even amount to 100%.

As schematically illustrated in FIG. 2, the IGBT 1 may comprise a first control terminal 13-A and a second control terminal 13-B. In an embodiment, the first control terminal 13-A is electrically insulated from the second control terminal 13-B. The first control signal 13-21 may be provided via the first control terminal 13-A, and the second control signal 13-22 may be provided via the second control terminal 13-B. Contrary to the schematic illustration in FIG. 2, according to which the control terminals 13-A and 13-B are arranged within the IGBT regions 1-21, 1-22, respectively, but, e.g., the control terminals 13-A and 13-B may be arranged external thereof, e.g., in another part of the active region 1-2 or in the edge termination region 1-3 or yet somewhere else. Ways of implementing an electrical connection between the control electrodes associated with the first control terminal 13-A and an electrical connection between the control electrodes associated with the second control terminal 13-B are known to the skilled person and are hence herein not explained.

For example, the second control signal 13-22 is independent of the first control signal 13-21. For example, the second control signal 13-22 may at least temporarily differ from the first control signal 13-21. For example, the second control signal 13-22 is generated separately from the first control signal 13-21. Thereby, the control of the forward load current in the first IGBT region 1-21 can be independent of the control of the forward load current in the second IGBT region 1-22. This said, it shall be understood that in some embodiments, the second IGBT region 1-22 may be controlled based on both the first control signal 13-21 and the second control signal 13-22.

In accordance with embodiments described herein, the first IGBT region 1-21 may exhibit a configuration different from a configuration of the second IGBT region 1-22.

For example:
a first MOS-channel-conductivity-to-area-ratio is determined by a total channel width in the first IGBT region 1-21 and a total lateral area of the first IGBT region 1-21; and
a second MOS-channel-conductivity-to-area-ratio is determined by a total channel width in the second IGBT region 1-22 and a total lateral area of the second IGBT region 1-22; and
the second MOS-channel-conductivity-to-area-ratio amounts to less than 80% of the first MOS-channel-conductivity-to-area-ratio.

The conditions above may apply if both the first control signal 13-21 and the second control signal 13-22 exhibit a respective voltage value corresponding to the (nominal) ON state, i.e., the forward conduction state, of the IGBT 1. For example, the conditions above apply if both the first control signal 13-21 and the second control signal 13-22 exhibit a value of, e.g., +15 V, or +8V or the like.

That is, the second MOS-channel-conductivity-to-area-ratio may be different from the first MOS-channel-conductivity-to-area-ratio. For example, the second MOS-channel-conductivity-to-area-ratio amounts to less than 80% of the first MOS-channel-conductivity-to-area-ratio or even less than 60% of the first MOS-channel-conductivity-to-area-ratio.

Additionally or alternatively to the example explained in the preceding two paragraphs, the following may apply:
the first IGBT region 1-21 includes first MOS-channels exhibiting a first threshold voltage; and
the second IGBT region 1-22 includes second MOS-channels exhibiting a second threshold voltage amounting to at least 115% of the first threshold voltage.

Accordingly, the second threshold voltage present in the second IGBT region 1-22 may be greater than the first threshold voltage present in the first IGBT region 1-21. For example, second threshold voltage amounts to at least 120% of the first threshold voltage or to even more than 130% of the first threshold voltage.

Based on the different configurations of the two IGBT regions 1-21 and 1-22 and based on the two control signals 13-21 and 13-22, a beneficial switching behavior may be achieved, together with an improved device robustness. For example, the second IGBT region 1-22 is configured to temporarily conduct, while the second control signal 13-22 corresponds to a nominal ON-state of the IGBT 1 and while the first control signal 13-21 transitions or corresponds to an OFF-state of the IGBT 1, at most three times of the IGBT's nominal forward load current. That is, while the first IGBT region 1-21 is turned-OFF to block flow of the forward load current in the first IGBT region 1-21, the entire device forward load current may temporarily be conducted by only the second IGBT region 1-22, which can be turned-OFF after turn-OFF of the first IGBT region 1-21, even in case of overload current amounting up to three times of the IGBT's nominal forward load current. For example, this may reduce the total amount of charge carriers stored in the IGBT 1 before turning off the current finally. Thereby the turn-off losses are reduced.

For example, a further possible difference in the configurations of the two IGBT regions 1-21 and 1-22 may be achieved based on a body region 102 (cf. FIG. 3). For example, the body region 102 extends in both the first IGBT region 1-21 and the second IGBT region 1-22, wherein an average dopant dose of the second IGBT region's body region amounts to at least 120% of the first IGBT region's body region dopant dose. Said difference may be even more significant; e.g., the average dopant dose of the second IGBT region's body region amounts to at least 140% of the first IGBT region's body region dopant dose. For example, the first and second MOS-channels described above may be induced within the body region 102 based on the first control signal 13-21 and the second control signal 13-22. Such difference in body dose may also yield a corresponding difference of the threshold voltages in the IGBT regions 1-21 and 1-22, as exemplarily described above.

Increasing, compared to the first IGBT region 1-21, the dopant concentration of the body region 102 in the second IGBT region 1-22 may decrease the resistance for the holes (charge carriers) in the body region 102 of the second IGBT region 1-22, which may yield, in the second IGBT region 1-22, an increased latch-up robustness and an improved capability of temporarily conducting an overload current. Part of the second IGBT region 1-22 may have the same body dopant as it is in the first IGBT region 1-21. However, the source region 101 are placed within the higher doped p-body part. Also in the first IGBT region 1-21, the dopant concentration of the body region 102 may be locally increased to achieve such increased latch-up robustness. For the structured p-body dose in the first IGBT region 1-21 one can have different threshold voltages, if n-source regions 101 are located in the both parts. There can be a larger area of 1-21 with lower p-body dose and another large area with higher p-body dose. In case of an overcurrent turn-off with a re-turn of the G1 voltage [explained later in Abs. 121], there is a certain voltage window, in which only the part with lower p-body dose turns on.

It shall be understood that the first IGBT region 1-21 and the second IGBT region 1-22 form a major portion of the active region 1-2. For example, the sum of the first IGBT region 1-21 and the second IGBT region 1-22 amounts to at least 80%, to at least 90% or to even more than 95% of the active region 1-2. Further, each of the first IGBT region 1-21 and the second IGBT region 1-22 may amount to at least 30% of the active region 1-2.

The first IGBT region 1-21 may be larger than the second IGBT region 1-22. For example, the first IGBT region 1-21 is at least twice as large as the second IGBT region 1-22.

According to an example, the first IGBT region 1-21 is configured to be controlled based only on a first control signal 13-21 and the second IGBT region 1-22 is configured to be controlled based on the second control signal 13-22. Optionally, the second IGBT region 1-22 may configured to be controlled based on the first and the second control signal 13-21, 13-22. The forward saturation current of the second IGBT region 1-22 may in this example be limited by the chip design. For example, a saturation current of the forward load current of the IGBT 1 with only the second IGBT region 1-22 being in a forward conducting state may be most three or even at most two times a nominal value for the forward load current of the IGBT 1 with both IGBT regions 1-21 and 1-22 being in a forward conducting state. In other words, a saturation current of the forward load current of the IGBT 1 with only the second control signal 13-22 being in a forward conducting state may be most three or even at most two times a nominal value for the forward load current of the IGBT 1. Alternatively or additionally, the forward saturation current of the second IGBT region 1-22 (with only the second control signal 13-22 being in a conductive state) may be limited by the chip design to a smaller value than the first IGBT region 1-21 (with the first control signal 13-21 being in a conductive state). For example, the share of the forward saturation current of the second IGBT region 1-22 (with only the second control signal 13-22 being in a conductive state) may be at least 10% smaller or even at least 20% smaller than the share of the second IGBT region 1-22 to total active IGBT area of the IGBT 1.

As will be explained further below, based on the first and second control signals 13-21 and 13-22, the first IGBT region 1-21 and the second IGBT region 1-22 may be switched asynchronously. For example, the second IGBT region 1-22 may be turned on with a certain time delay before or after turning on the first IGBT region 1-21. In addition, the second IGBT region 1-22 may be turned off with a certain time delay after turning on the first IGBT region 1-21. This case could in so far be problematic that because the second IGBT region 1-22 may be comparatively small, a current density may increase above a critical level as the entire or almost the entire load current must temporarily be conducted by the second IGBT region 1-22 if the first IGBT region 1-21 is turned off before turning off the second IGBT region 1-22.

To this end, it is herein proposed to design the second IGBT region 1-22 such that it exhibits high robustness, e.g., by limiting the second MOS-channel-conductivity-to-area-ratio, as exemplarily explained above. There are many possibilities to limit the second MOS-channel-conductivity-to-area-ratio, some of which being described below, such as corresponding configurations of at least one of a source region, a body region, and a trench-mesa pattern in the second IGBT region 1-22.

Each of the first IGBT region 1-21 and the second IGBT region 1-22 may exhibit a total lateral extension of at least 60% of the vertical thickness d of the semiconductor body 10. One or both of said total lateral extensions may even be greater, such as at least 100%, 150% or even more than 200% of the vertical thickness d of the semiconductor body 10.

The first IGBT region 1-21 is spatially separated from the second IGBT region 1-22; e.g., there is no spatial overlap between the first IGBT region 1-21 and the second IGBT region 1-22. The first IGBT region 1-21 may be a (single) first contiguous region and the second IGBT region 1-22 can be a (single) second contiguous region. In other embodiments, the first IGBT region 1-21 is divided into two or more spatially distributed first subregions, and the second IGBT region 1-22 is divided into two or more spatially distributed second subregions. Even in the latter case, there is no lateral overlap between the first subregions constituting the first IGBT region 1-21 and the second subregions constituting the second IGBT region 1-22.

In addition to the first IGBT region 1-21 and the second IGBT region 1-22, the active region 1-2 may optionally comprise a diode-only region 1-23, e.g., if the IGBT 1 is configured as an RC IGBT, which will be explained in more detail below.

If provided, the diode-only region 1-23 can be smaller than each of first IGBT region 1-21 and the second IGBT region 1-22. The diode-only region 1-23 can have a total lateral extension of at least 40% of the vertical thickness d of the semiconductor body 10. For example, at least 90% of the optional diode-only region 1-23 is configured to conduct only the reverse load current (but, e.g., not the forward load current). In an embodiment, the diode-only region 1-23 is not subjected to the first control signal 13-21 or the second control signal 13-22. For example, the diode-only region 1-23 does not comprise any control trench. Furthermore, it may be provided that the diode-only region 1-23 does not comprise any semiconductor source region 101 electrically connected to the first load terminal 11.

It shall be understood that the arrangement of the first IGBT region 1-21, the second IGBT region 1-22 and the optional diode-only region 1-23 as illustrated in FIG. 2 is only exemplary. For example, said regions 1-21, 1-22 and 1-23 need not necessarily be contiguous regions but could also be constituted by spatially distributed subregions, as explained above. Also, instead of being centrally arranged, the first IGBT region 1-21 could alternatively or additionally be arranged in periphery portions of the active region 1-2. For example, said regions 1-21, 1-22 and (optionally) 1-23 may exhibit a respective rectangular lateral circumference and may be arranged in accordance with a stripe pattern in the active region 1-2. The latter variant could facilitate providing of the control signals to the regions 1-21 and 1-22.

Thus, the skilled person may dimension and arrange said three regions 1-21, 1-22 and 1-23 within the active region 1-2 according to the designated characteristics of the IGBT 1 and further circumstances.

Furthermore, the formulation “at least 90%” used within the context of describing these regions shall express that the primary purpose of the regions is conduct either the forward load current only (in case of the first IGBT region 1-21), or the reverse load current only (in case of the optional diode-only region 1-23), or, for example, both the forward load current and the reverse load current (in case of a certain configuration the second IGBT region 1-22).

In an embodiment, the characteristics of said regions may deviate in respective smaller subportions of 10% or less of said regions, e.g., in a transition region where one of the regions 1-21, 1-22 and 1-23 adjoins another one of these regions. Such transitions will be described further below in more detail.

Reference will now be made in more detail to FIG. 3, which illustrates a section of a vertical cross-section of an exemplary embodiment of the active region 1-2, including the first IGBT region 1-21, the second IGBT region 1-22 and the diode-only region 1-23. It is again emphasized that the diode-only region 1-23 is optional. In other embodiments, no diode-only region 1-23 is provided.

As illustrated, the active region 1-2 exhibits a vertical configuration with the first load terminal 11 being arranged at the semiconductor body front side 110 and the second load terminal 12 being arranged at the semiconductor body back side 120. The first load terminal 11 and the second load terminal 12 may be shared by each of the first IGBT region 1-21, the second IGBT region 1-22 and the diode-only region 1-23.

A drift region 100 of the first conductivity type may form the major central portion of the semiconductor body 10 with respect to the vertical direction Z. This drift region 100 may be shared by each of the first IGBT region 1-21, the second IGBT region 1-22, and (if present) by the diode-only region 1-23.

The active region 1-2 may be configured, both at the front side 110 and at the back side 120, according to the distribution of the first IGBT region 1-21, the second IGBT region 1-22, and (if present) the diode-only region 1-23.

For example, regarding the back side 120, in electrical connection with the second load terminal 12, there is arranged a back side emitter 108 coupled to the drift region 100, wherein the back side emitter 108 is configured in accordance with the separation of the active region 1-2 into at least the first IGBT region 1-21, the second IGBT region 1-22, and (if present) the diode-only region 1-23.

The illustrated exemplary IGBT 1 exhibits an RC IGBT configuration. In such case, the following may apply:
the first IGBT region 1-21 exhibits an IGBT-only configuration for conduction of only the forward load current; and
the second IGBT region 1-22 exhibits an RC IGBT configuration for conduction of both the forward load current and a reverse load current; and, optionally,
the diode-only region 1-23 exhibits a diode-only configuration for conduction of only the reverse load current.

Accordingly, the capability to conduct a reverse load current is established by the second IGBT region 1-22 and the optional diode-only region 1-23. In an embodiment, the back side emitter 108 may reflect this configuration and may comprise:
a first section 108-21 of the second conductivity type in a portion of the active region 1-2 where the first IGBT region 1-21 (IGBT-only region 1-21) is present;
a second section 108-22 including both first subsections 108-221 of the first conductivity type and second subsections 108-222 of the second conductivity type in a portion of the active region 1-2 where the second IGBT region 1-22 (RC IGBT region 1-22) is present;
and, optionally, if the diode-only region 1-23 is implemented, a third section 108-23 of the first conductivity type in a portion of the active region 1-2 where the diode-only region 1-23 is present.

For example, the first section 108-21 of the back side emitter 108 is of only the second conductivity type. That is, in an embodiment, the first section 108-21 does not comprise any portions of the first conductivity type.

Furthermore, the first section 108-21 of the back side emitter 108 may exhibit, with respect to its horizontal area, an average dopant dose of at least 5*10¹² cm⁻². Said average dopant dose can be even greater, e.g., amount to at least 1*10¹³ cm⁻² or 1*10¹⁴ cm⁻². This said, in an embodiment, the first section 108-21 of the back side emitter 108 may exhibit, along at least one of the first lateral direction X and the second lateral direction Y, a variation of the dopant concentration and/or dopant dose.

Now regarding the second section 108-22 of the back side emitter 108, in an embodiment where the second IGBT region 1-22 exhibits an RC IGBT configuration, each of the first subsections 108-221 of the second section 108-22 of the back side emitter 108 exhibits, with respect to its horizontal area, an average dopant dose of at least 1*10¹⁴ cm⁻². Said average dopant dose can be even greater, e.g., amount to at least 5*10¹⁴ cm⁻² or 1*10¹⁵ cm⁻².

In another embodiment, where the second IGBT region 1-22 exhibits a regular IGBT (i.e., not an RC IGBT) configuration, the second section 108-22 of the back side emitter 108 may be equally configured, in terms of thickness and dopant concentration, as the first section 108-21. It can, however, be advantageous for lower turn-off losses to provide the second section 108-22 of the back side emitter 108 with a lower average dopant dose than the average dopant dose of the first section 108-21 of the back side emitter 108. For such a structure it can be beneficial to extend the second section 108-22 into the low sat. IGBT region 1-21 in such a way that the overlap between 108-22 and 1-21 is in the range between 0.3 and 3 times d, e.g. between 0.5 and 1 times d.

Further, each of the first subsections 108-221 can be displaced from the diode-only region 1-23 by a second distance d2 of at least 20% of the thickness d of the semiconductor body 10. For example, based on the second distance d2, it may be ensured that the influence of both the first control signal 13-21 and the second control signal 13-22 on the diode-only region 1-23 is small.

In case the diode-only region 1-23 is provided, the third section 108-23 of the back side emitter region 108 can be a region of only the first conductivity type. In another embodiment, the third section 108-23 may include (non-illustrated) subsections of the second conductivity type that are also electrically connected to the second load terminal, e.g., “p-shorts” similar to the “n-shorts”/first subsections 108-221 of the first conductivity type in the second section 108-22 of the back side emitter 108.

In an embodiment, the IGBT 1 further comprises a field stop region 107 of the first conductivity type coupled with both the drift region 100 and the back side emitter 108. The dopant concentration of the field stop region 107 can be greater than the dopant concentration of the drift region 100. For example, the dopant concentration of the field stop region 107 amounts to at least ten times of the dopant concentration of the drift region 100.

As illustrated, the thicknesses of the first section 108-21, the second section 108-22 and, if implemented, the third section 108-23 of the back side emitter 108 may vary. For example, the third section 108-23 of the back side emitter 108 in the optional diode-only region 1-23 may be thinner than the remaining sections 108-21 and 108-22 of the back side emitter 108. There, the field stop region 107 may be thicker as compared to its remaining portion laterally overlapping with the sections 108-21 and 108-22 of the back side emitter 108. Said configuration of the back side emitter 108 and the field stop layer 107 in the optional diode-only region 1-23 may extend into the second IGBT region 1-22 along a path corresponding to the distance d2, as illustrated.

As indicated above, the configuration of the active region 1-2 may also at the front side 110 reflect the active region's 1-2 separation into the at least the first IGBT region 1-21, the second IGBT region 1-22 and, if implemented, the diode-only region 1-23.

For example, the RC IGBT 1 further comprises, between the first load terminal 11 and the drift region 100, a trench-mesa-pattern, wherein the trench-mesa-pattern is configured in accordance with the separation of the active region 1-2 into at least the first IGBT region 1-21, the second IGBT region 1-22 and, if implemented, the diode-only region 1-23. This will be described in more detail below:

An exemplary configuration of the trench-mesa-pattern at the front side 110 is illustrated in FIG. 3. The illustrated trench-mesa-pattern comprises first control trenches 14-21 configured to receive the first control signal 13-21 and second control trenches 14-22 configured to receive the second control signal 13-22. In terms of structure, the first control trenches 14-21 and the second control trenches 14-22 may be equally configured.

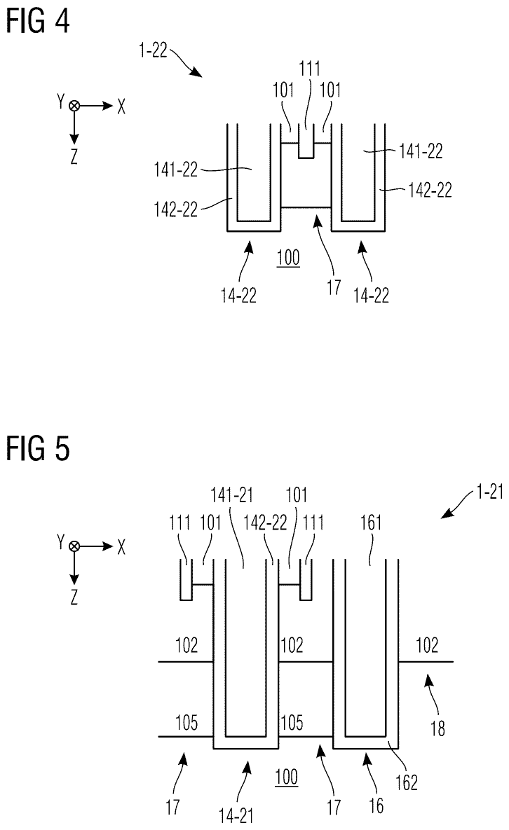

These control trenches 14-21 and 14-22 are exemplarily illustrated in FIGS. 4 and 5. For example, each second control trench 14-22 includes a second control trench electrode 141-22 configured to receive the second control signal 13-22 (Gate 2). The second control trench electrode 141-22 is isolated from the semiconductor body 10 based on the second control trench insulator 142-22. As the second control trench 14-22, each first control trench 14-21 may include a first control trench electrode 141-21 configured to receive the first control signal 13-21 (Gate 1). The first control trench electrode 141-21 is isolated from the semiconductor body 10 based on the first control trench insulator 142-21.

For example, each first control trench electrode 141-21 is electrically connected to the first control terminal 13-A. Analogously, each second control trench electrode 141-22 can be electrically connected to the second control terminal 13-B.

For example, the first IGBT region 1-21 comprises a plurality of the first control trenches 14-21, but, optionally, none of the second control trenches 14-22. That is, in an embodiment, the first IGBT region 1-21 is controlled solely based on the first control trenches 14-21, as none of the second control trenches 14-22 is present in the first IGBT region 1-21.

Further, the second IGBT region 1-22 may comprises a plurality of the second control trenches 14-22, but, optionally, none of the first control trenches 14-21. That is, in an embodiment, the second IGBT region 1-22 is controlled solely based on the second control trenches 14-22, as none of the first control trenches 14-21 is present in the RC IGBT region 1-22. In another embodiment, a subset of the first control trenches 14-21 is arranged in the second IGBT region 1-22; then, the second IGBT region 1-22 may be controlled based on both the first control signal 13-21 and the second control signal 13-22. According to one embodiment, the source regions 101 are only placed next to 14-22. In another embodiment, source regions 101 are present next to both second control trenches 14-22 and first control trenches 14-21.

In an embodiment, the trench-mesa-pattern further comprises source trenches 16 electrically connected to the first load terminal 11 and arranged at least in the first IGBT region 1-21. For example, referring to FIG. 5, each source trench 16 may include a source trench electrode 161 electrically connected to the first load terminal 11. The source trench electrode 161 is isolated from the semiconductor body 10 based on the source trench insulator 162.

In an embodiment, a subset of the source trenches 16 may be arranged also in the second IGBT region 1-22 and, if implemented, in the diode-only region 1-23.

In another embodiment, as illustrated in FIG. 3, the second IGBT region 1-22 does not comprise any source trench 16.

For example, the diode-only region 1-23 comprises only source trenches 16, but no control trenches.

For example, contrary to the illustration in FIG. 3, in the second IGBT region 1-22, the first and second control trenches 14-21/14-22 may be arranged in an alternating manner along the first lateral direction X, and between each pair of control trenches 14-21/14-22, there is/are arranged one or more source trenches 16.

In the first IGBT region 1-21, there may for example be arranged one, two or more source trenches 16 between respective two adjacent first control trenches 14-21.

Also referring to FIGS. 4 and 5, in an embodiment, the trench-mesa-pattern further comprises first type mesas 17 arranged in both the first IGBT region 1-21 and the second IGBT region 1-22. Each first type mesa 17 includes a source region 101 of the first conductivity type and a portion of said body region 102 of the second conductivity type. For the sake of a clear representation, only a few of the source regions 101 present in the second IGBT region 1-22 are provided with a respective reference sign. Each bold little square represents a source region 101. Furthermore, each illustrated trench in the RC IGBT region 1-22 represents one of the pluralities of the first control trenches 14-21, the second control trenches 14-22 and the source trenches 16, wherein each of the second control trenches 14-22 is arranged adjacent to one of the first type mesas 17 in the second IGBT region 1-22.

In each first type mesa 17, both the source region 101 and the body region 102 are electrically connected to the first load terminal 11. For example, to this end, a first contact plug 111 may be employed. At least the body region 102 isolates the source region 101 from the drift region 100.

In the first IGBT region 1-21, each first type mesa 17 is arranged adjacent at least one of the first control trenches 14-21. There, each first control trench 14-21 is configured to induce, in response to receiving a corresponding configuration of the first control signal 13-21, a conductive channel (i.e., one of said first MOS-channels) in the adjacent first type mesa 17 for conduction of the forward load current. Such a conductive channel induction is generally known to the skilled person and accordingly not explained in further detail here.

In the second IGBT region 1-22, each first type mesa 17 is arranged adjacent at least one of the second control trenches 14-22 or, if present in the second IGBT region 1-22, the first control trenches 14-21. There, each first/second control trench 14-21/14-22 is configured to induce, in response to receiving a corresponding configuration of the first/second control signal 13-22/13-211, a conductive channel (i.e., one of said second MOS-channels) in the adjacent first type mesa 17 for conduction of the forward load current. As indicated above, such a conductive channel induction is generally known to the skilled person and accordingly not explained in further detail here.

If first control trenches 14-21 are provided in the second IGBT region 1-22, the number of second control trenches 14-22 present in the second IGBT region 1-22 may be at least 40% of the number of first control trenches 14-21 present in the second IGBT region 1-22. For example, in the second IGBT region 1-22, the first control trenches 14-21 and the second control trenches 14-22 are arranged in an alternating manner with respect to a first lateral direction X. For example, between each pair of control trenches 14-21/14-22, there is arranged a number of (zero, one, or more than one) source trenches 16.

For example, at least in the first IGBT region 1-21 and optionally in the second IGBT region 1-22, the trench-mesa-pattern may further comprise second type mesas 18 that are not equipped with a source region 101 and that may or may not be electrically connected to the first load terminal 11. Further, additional trench types, such as floating trenches (whose trench electrodes are not electrically connected to a defined potential) or further control trenches may be provided. In another embodiment, each mesa in the first IGBT region 1-21 is a mesa 17 of the first type.

For example, in the optionally provided diode-only region 1-23, only source trenches 16 but no control trenches are provided. These source trenches 16 may laterally confine diode mesas 19 in the diode-only region 1-23, wherein, there, the body region 102 is electrically connected to the first load terminal 11. The diode mesas 19 are laterally confined by the source trenches 16.

The trench-mesa-pattern illustrated in FIG. 3 is an example. In another embodiment, trench-mesa-patterns different therefrom may be provided.

Here, it shall be understood that the configurations of the front side 110 and the back side 120, i.e., the trench-mesa-pattern at the front side 110 and the back side emitter 108 at the back side 120, can be aligned with each other according to the separation of the active region 1-2 into the second IGBT region 1-22, the first IGBT region 1-21 and the optional diode-only region 1-23.

That is, in an embodiment,
the above explained trench-mesa-configuration in the first IGBT region 1-21 laterally overlaps with the above explained configuration of the first section 108-21 of the back side emitter 108 in the first IGBT region 1-21;
the above explained trench-mesa-configuration in second IGBT region 1-22 laterally overlaps with the above explained configuration of the second section 108-22 of the back side emitter 108 in the second IGBT region 1-22; and
the above explained trench-mesa-configuration in diode-only region 1-23 laterally overlaps with the above explained configuration of the third section 108-23 of the back side emitter 108 in the diode-only region 1-23.

In an embodiment, the IGBT 1 further comprises a barrier region 105 of the first conductivity type that couples the trench-mesa-pattern in the first IGBT region 1-21 to the drift region 100. For example, the dopant concentration of the barrier region 105 is greater than the dopant concentration of the drift region 100.

As illustrated in FIG. 3, the barrier region 105 is for example only provided in the first IGBT region 1-21, but provided neither in the second IGBT region 1-22 nor in the optional diode-only region 1-23.

Based on the above-described exemplary design, the first IGBT region 1-21 may constitute a low saturation IGBT that is controlled based on the first control signal 13-21 (Gate 1), and the second IGBT region 1-22 may constitute an RCDC IGBT region with reverse conductivity (RC) and diode control (DC) characteristic that is controlled based on the second control signal 13-22 (Gate 2) and optionally also based on the first control signal 13-21 (Gate 1).

FIG. 4 illustrates a more detailed example of a section of the second IGBT region 1-22. Accordingly, a first type mesa 17 is arranged between two of the second control trenches 14-22. A respective source region 101 is provided adjacent to each of the second control trenches 14-22, such that each of the two second control trenches 14-22 may induce a respective second MOS-channel in the first type mesa 17. However, in another embodiment, only one source region 101 (e.g., arranged to only one control trench) is provided in the first type mesa 17 in the second IGBT region 1-22, e.g., to ensure that the second MOS-channel-conductivity-to-area-ratio in the second IGBT region 1-22 amounts to less than 80% of the first MOS-channel-conductivity-to-area-ratio in the first IGBT region 1-21.

FIG. 5 illustrates a more detailed example of a section of the first IGBT region 1-21. There, the first type mesa 17 is for example laterally flanked by only one of the first control trenches 14-21. The other trench laterally confining the first type mesa 17 may for example be one of the source trenches 16. Thus, in each first type mesa 17, the source region 101 is arranged laterally adjacent to only the first control trench 14-21. Accordingly, instead of two first MOS-channels in the first type mesa, there is only one first MOS-channel per first type mesa 17 in the first IGBT region 1-21. Also there, two second type mesas 18 or one of the second type mesas 18 and one of the first type mesa 17 can be arranged adjacent to each source trench 16. In another embodiment, two source regions are provided in the first type mesa 17 in the first IGBT region 1-21 (or, respectively, one source region 101 that extends along the entire width of the first type mesa 17), e.g., to ensure that the second MOS-channel-conductivity-to-area-ratio in the second IGBT region 1-22 amounts to less than 80% of the first MOS-channel-conductivity-to-area-ratio in the first IGBT region 1-21.

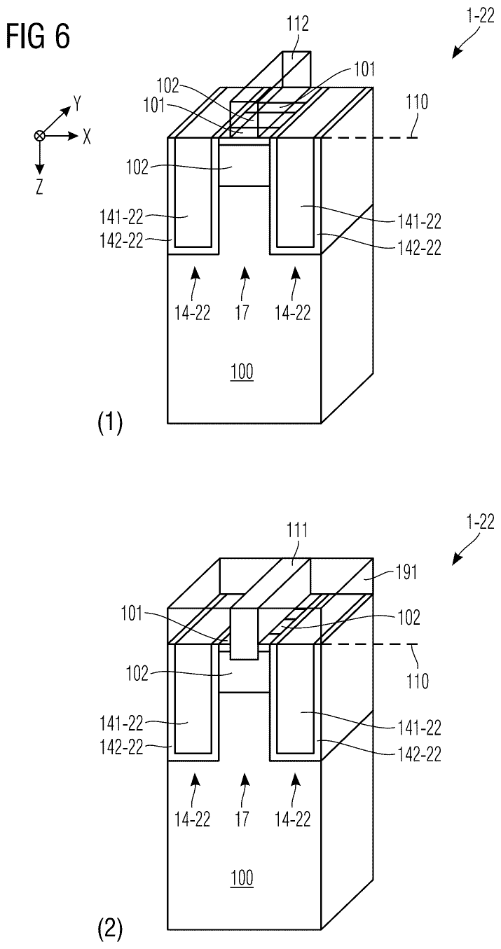

As illustrated in FIG. 6, the first type mesas 17 may be electrically contacted based on a contact plug 111 (cf. variant (2)) that extends below the first surface 110 and that adjoins an insulation region 191. Alternatively, a planar contact 112 that terminates approximately at the surface 120 (cf. variant (1)) may be used.

Irrespective of the manner of electrically contacting the first type mesas 17, the first type mesas 17 in the second IGBT region 1-22 may be configured such that the active channel is divided into a plurality of second MOS-channels that are comparatively small in width. Such configuration, which can for example be achieved, as illustrated in FIG. 6, based on a corresponding lateral structure of the source regions 101 in each first type mesa 17, is one further possibility to limit the second MOS-channel-conductivity-to-area-ratio in the second IGBT region 1-22 to a designated value. Furthermore, similar as the possible increased dopant concentration of the body region 102 in the first type mesas 17 of the second IGBT region 1-22, the division of the active channel into said plurality of small-width and along the second lateral direction Y spatially separated second MOS-channels may also yield an increased latch-up robustness of the second IGBT region 1-22.

The illustration in FIG. 6 is only exemplarily. The source region 101 could for example be laterally structured in different manners. For example, the source regions 101 are only provided at one side of the first type mesa 17 (e.g., on the left side of the contact plug or on the right side of the contact plug), or the source regions 101 could be arranged at the left and the right side in an alternating manner along the second lateral direction Y.

According to a further embodiment, in the second IGBT region 1-22, the body region 102 in one or more of the first type mesas 17 exhibits a variation of the dopant concentration along the second lateral extension of the respective first type mesa 17. For example, the source regions 101 in the respective first type mesa 17 laterally overlap with those sections of the body region 102 exhibiting a comparatively high dopant concentration. For example, based on such configuration of the body region 102, the load current dependency of the anode efficiency during reverse load current conduction can be adjusted.

The above described differences between the first IGBT region 1-21 and the second IGBT region 1-22 may for example be achieved or, respectively, supported if it is provided that percentual area share occupied by the source region 101 in the first IGBT region 1-21 is greater than the percentual area share occupied by the source region 101 in the second IGBT region 1-22.

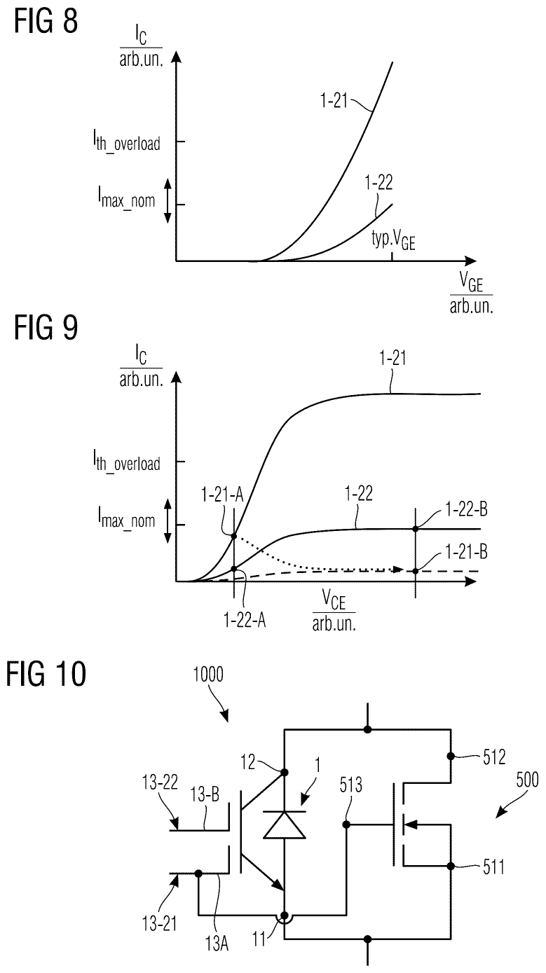

Due to their difference in configuration, the second region 1-22 may exhibit a transfer characteristic and an output characteristic that are different from the transfer and output characteristics of the first IGBT region 1-21. This aspect is exemplarily illustrated in FIGS. 8 to 10.

In FIG. 8, the horizontal axis indicates the voltage V_{GE} of the first and second control signals (which are identical in the illustrated example), and in FIGS. 9 and 10, the respective horizontal axis indicates voltage V_{CE} across the first load terminal 11 and the second load terminal 12. In each of FIGS. 8 to 10, the vertical axis indicates the forward load current I_{C}.

In FIG. 8, the IGBT 1 is forward biased, i.e., the voltage V_{CE} across the first load terminal 11 and the second load terminal 12 is positive to allow for flow of the forward load current I_{C}. In FIGS. 9 and 10, both the first control signal 13-21 (Gate 1) and the second control signal 13-22 (Gate 2) exhibit a configuration corresponding to an ON state of the RC IGBT 1.

According to the illustrated examples, as can be derived from FIG. 8, the second MOS-channels in the second IGBT region 1-22 exhibit the second threshold voltage amounting to at least 115% of the first threshold voltage of the first MOS-channels in the first IGBT region 1-21. That is, at same voltage levels of the first and the second control signals 13-21 and 13-22, the share of the forward load current in the second IGBT region 1-22 is smaller than the share of the forward load current in the first IGBT region 1-21. Furthermore, the second IGBT region 1-22 may be arranged such that for a value only of the second control signal 13-22 corresponding to an ON state (while the first control signal 13-21 is corresponding to an OFF state), the forward load current is at most 300% or only at most 200% of the nominal load current (I_{max_nom}) or even smaller than the nominal load current (I_{max_nom}) of the complete IGBT 1. By contrast, with corresponding conditions, the forward load current in the first IGBT region 1-21 would be much greater, e.g., at level corresponding to an overload situation (I_{th_overload}).

A pitch of the trench-mesa-pattern in the first IGBT region 1-21 may be identical to a pitch of the trench-mesa-pattern in the second IGBT region 1-22; and/or a mesa width in the trench-mesa-pattern in the first IGBT region 1-21 may be identical to a mesa width in the trench-mesa-pattern in the second IGBT region 1-22; and/or a trench width in the trench-mesa-pattern in the first IGBT region 1-21 may be identical to a trench width in the trench-mesa-pattern in the second IGBT region 1-22.

For example, the geometric dimensions related to the mesas 17 and 18 and the trenches 14-21, 14-22 and 17 in the first IGBT region 1-21 may be identical to the corresponding geometric dimensions in the second IGBT region 1-22.

Presented herein is also a method of operating an IGBT 1 according to one of the preceding embodiments. The method comprises controlling the IGBT 1 based on the first control signal 13-21 (Gate 1) and the second control signal 13-22 (Gate 2).

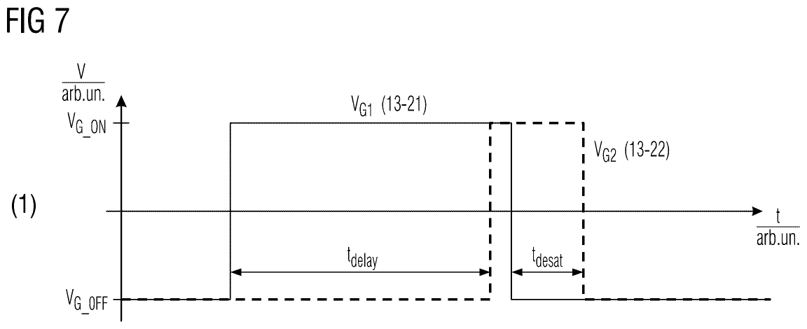

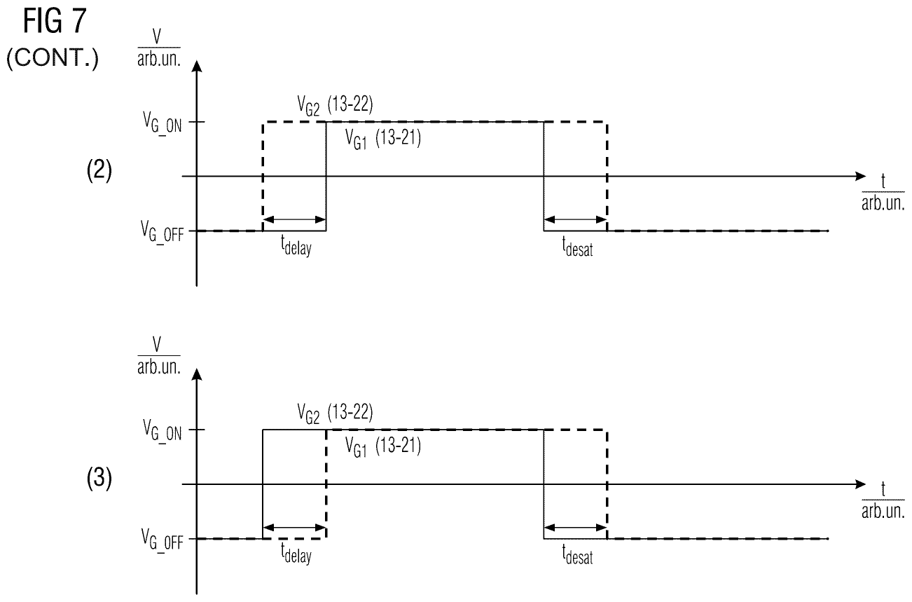

Some examples (1) to (3) of such method are illustrated in FIG. 7 which will now be referred to. In each example, the first control signal 13-21 is illustrated with a continuous path denoted V_{G1} (i.e., voltage of the first control signal 13-21 (Gate 1)), and the second control signal 13-22 is illustrated with a dashed path denoted V_{G2} (i.e., voltage of the second control signal 13-22 (Gate 2)).

As usual, the first control signal 13-21 can be generated by providing a voltage between the first control terminal 13-A and the first load terminal 11, wherein the first control terminal 13-A is electrically connected with the first control trench electrodes 141-21. Likewise, the second control signal 13-22 can be generated by providing a voltage between the first load terminal 11 and the second control terminal 13-B and the first load terminal 11, wherein the second control terminal 13-B is electrically connected with the second control trench electrodes 141-22.

The voltage is indicated at the vertical axis, the horizontal axis in each example indicates the time. A positive value V_{G_ON} of the voltage (e.g., +15 V) corresponds to an ON state (forward conduction state) and a negative or zero voltage V_{G_OFF} value (e.g., −8V or −15V) corresponds to an OFF state (forward blocking state) of the IGBT 1. Whereas the voltage values V_{G_ON}, V_{G_OFF} corresponding to these states may be identical for both the first control signal 13-21 and the second control signal 13-22, the timings of changing the values from one to the other to cause a switching operation may differ between the first control signal 13-21 and the second control signal 13-22.

According to example (1), the second IGBT region 1-22 is primarily used to improve the turn-off process. For example, the second IGBT region 1-22 is turned on with a time delay t_{delay}, e.g., shortly before the first IGBT region 1-21 is turned off. The second IGBT region 1-22 remains in the ON state while the first IGBT region 1-21 is turned off. As explained above, the load current is then temporarily—completely or only partly, depending on the load current level—carried by the second IGBT region 1-22. The IGBT 1 is then desaturated (cf. time period t_{desat}) until it is completely turned off based on also changing the second control signal 13-22 to the V_{G_OFF} value. Depending on the application, as illustrated in example (3), the delay t_{delay} with which the second IGBT region 1-22 is turned on may be reduced or even, cf. example (2), turned into a negative value, meaning that the second IGBT region 1-22 is turned on before the first IGBT region 1-21 is turned on. Examples (2) and (3) can be beneficial for low on-state voltage but may lead to higher turn-off losses. Example (2) may allow a better control of the turn-on process. However, in each of the three examples, the second control signal 13-22 is provided such that the second IGBT region 1-22 is in the forward conduction state while the first IGBT region 1-21 is switched into the forward blocking state based on the first control signal 13-21; e.g., the second IGBT region 1-22 is turned off after the turn-off of the first IGBT region 1-21 to allow the IGBT 1 to desaturate.

FIG. 10 schematically and exemplarily illustrates a circuit 1000 in accordance with one or more embodiments. The circuit 1000 comprises an IGBT 1 according to one of the above described embodiments and a MOSFET 500 connected in parallel to the IGBT 1. For example, the first load terminal 11 of the IGBT 1 is electrically connected with a first load terminal 511 of the MOSFET 500, and the second load terminal 12 of the IGBT 1 is electrically connected with a second load terminal 512 of the MOSFET 500.

In an example, the IGBT 1 exhibits an RC IGBT configuration, e.g., as described exemplarily above. Further, the MOSFET 500 can be based on a wide-bandgap semiconductor material. For example, the MOSFET 500 is a silicon carbide, SiC, MOSFET. The IGBT 1, however, may be based on silicon, Si. In general, one can place instead of 500 a unipolar transistor, that could be alternatively to a MOSFET also an GaN HEMT.

The MOSFET 500 can be controlled based on the first control signal 13-21. To this end, a control terminal 513 of the MOSFET 500 may be electrically connected with the first control terminal 13-A of the IGBT 1.

The design of the circuit 500, as explained above, includes the recognition that in such an arrangement the switching losses may be limited mainly to the IGBT 1, especially in the case of example (2) of the operating method described above. In case of an RC IGBT configuration of the IGBT 1, the RC functionality may also serve to take over reverse current in an overload case.

In the above, embodiments pertaining to IGBTs, and corresponding operating methods were explained. For example, these IGBTs are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixCl-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising”, “exhibiting” and the like are open ended terms that indicate the presence of stated elements or features, but do not preclude additional elements or features.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An IGBT, comprising:
in a single chip, an active region configured to conduct a forward load current between a first load terminal at a front side of a semiconductor body of the IGBT and a second load terminal at a back side of the semiconductor body,
wherein the active region (1-2) is separated into at least a first IGBT region and a second IGBT region,
wherein at least 90% of the first IGBT region is configured to conduct, based on a first control signal, the forward load current,
wherein at least 90% of the second IGBT region is configured to conduct, based on a second control signal, the forward load current,
wherein a first MOS-channel-conductivity-to-area-ratio is determined by a total channel width in the first IGBT region divided by a total lateral area of first IGBT region,
wherein a second MOS-channel-conductivity-to-area-ratio is determined by a total channel width in the second IGBT region divided by a total lateral area of the second IGBT region, and
wherein the second MOS-channel-conductivity-to-area-ratio amounts to less than 80% of the first MOS-channel-conductivity-to-area-ratio.

2. The IGBT of claim 1, further comprising:
a body region extending in both the first IGBT region and the second IGBT region,
wherein an average dopant dose of the body region in the second IGBT region amounts to at least 120% of the average dopant dose of the body region in the first IGBT region.

3. The IGBT of claim 1, wherein the second IGBT region is configured to temporarily conduct, while the second control signal corresponds to a nominal ON-state of the IGBT and while the first control signal transitions or corresponds to an OFF-state of the IGBT, at most three times of a nominal forward load current of the IGBT.

4. The IGBT of claim 1, wherein the second control signal is independent of the first control signal.

5. The IGBT of claim 1, wherein a sum of the first IGBT region and the second IGBT region amounts to at least 80% of the active region, and/or wherein each of the first IGBT region and the second IGBT region amounts to at least 30% of the active region.

6. The IGBT of claim 1, wherein the first IGBT region is spatially separated from the second IGBT region.

7. The IGBT of claim 1, further comprising:
a drift region of a first conductivity type in the semiconductor body,
wherein the drift region is shared by both the first IGBT region and the second IGBT region.

8. The IGBT of claim 7, further comprising:
a back side emitter in electrical connection with the second load terminal and coupled to the drift region,
wherein the back side emitter is configured in accordance with the separation of the active region into at least the first IGBT region and the second IGBT region.

9. The IGBT of claim 8, further comprising:
a diode-only region,
wherein at least 90% of the diode region is configured to conduct only the reverse load current.

10. The IGBT of claim 8, wherein the back side emitter is configured with:
a first section of a second conductivity type in a portion of the active region where the first IGBT region is present; and
a second section including both first subsections of a first conductivity type and second subsections of the second conductivity type in a portion of the active region where the second IGBT region is present.

11. The IGBT of claim 10, wherein the first section of the back side emitter exhibits, with respect to a horizontal area of the first section, an average dopant dose of at least 5*10¹² cm⁻².

12. The IGBT of claim 8, further comprising:
a field stop region of the first conductivity type and coupled with both the drift region and the back side emitter,
wherein a dopant concentration of the field stop region is greater than a dopant concentration of the drift region.

13. The IGBT of claim 1, wherein the IGBT has an RC IGBT configuration, and wherein the first IGBT region has an IGBT-only configuration for conduction of only the forward load current, wherein the second IGBT region has an RC IGBT configuration for conduction of both the forward load current and a reverse load current.

14. The IGBT of claim 1, further comprising:
a trench-mesa-pattern between the first load terminal and the drift region,
wherein the trench-mesa-pattern is configured in accordance with the separation of the active region into at least the first IGBT region and the second IGBT region.

15. The IGBT of claim 14, wherein the trench-mesa-pattern comprises:
first control trenches arranged in the first IGBT region and configured to receive the first control signal; and
second control trenches arranged in the second IGBT region and configured to receive the second control signal.

16. The IGBT of claim 14, wherein the trench-mesa-pattern comprises source trenches electrically connected to the first load terminal and arranged at least in the first IGBT region.

17. The IGBT of claim 14, wherein the trench-mesa-pattern comprises:
first type mesas arranged in both the first IGBT region and the second IGBT region,
wherein each first type mesa includes a source region of a first conductivity type and a portion of a body region of a second conductivity type,
wherein both the source region and the body region are electrically connected to the first load terminal, and
wherein at least the body region isolates the source region from the drift region.

18. The IGBT of claim 17, wherein a percentual area share occupied by the source region in the first IGBT region is greater than a percentual area share occupied by the source region in the second IGBT region.

19. The IGBT of claim 14, further comprising:
a barrier region of a first conductivity type that couples the trench-mesa-pattern in the first IGBT region to a drift region of the first conductivity type in the semiconductor body,
wherein the drift region is shared by both the first IGBT region and the second IGBT region,
wherein a dopant concentration of the barrier region is greater than a dopant concentration of the drift region.

20. An IGBT, comprising:
in a single chip, an active region configured to conduct a forward load current between a first load terminal at a front side of a semiconductor body of the IGBT and a second load terminal at a back side of the semiconductor body,
wherein the active region is separated into at least a first IGBT region and a second IGBT region,
wherein the first IGBT region includes first MOS-channels exhibiting a first threshold voltage,
wherein at least 90% of the first IGBT region is configured to conduct, based on a first control signal, the forward load current,
wherein the second IGBT region includes second MOS-channels exhibiting a second threshold voltage amounting to at least 115% of the first threshold voltage,
wherein at least 90% of the second IGBT region is configured to conduct, based on a second control signal, the forward load current.

21. An IGBT, comprising:
in a single chip, an active region configured to conduct a forward load current between a first load terminal at a front side of a semiconductor body of the IGBT and a second load terminal at a back side of the semiconductor body,
wherein the active region is separated into at least a first IGBT region and a second IGBT region,
wherein at least 90% of the first IGBT region is configured to conduct, based only on a first control signal, the forward load current,
wherein at least 90% of the second IGBT region is configured to conduct, based on a second control signal, the forward load current,
wherein a saturation current of the forward load current with only the second IGBT region being in a forward conducting state is at most three times a nominal value for the forward load current of the IGBT.

22. A method of operating the IGBT of claim 1, the method comprising:
controlling the first IGBT region based on the first control signal; and
controlling the second IGBT region based on the second control signal.

23. The method of claim 22, wherein the second control signal is provided such that the second IGBT region is in a forward conduction state while the first IGBT region is switched into a forward blocking state based on the first control signal.

24. A circuit, comprising:
the IGBT of claim 1;
a MOSFET connected in parallel to the IGBT.

25. The circuit of claim 24, wherein the IGBT has an RC IGBT configuration and/or the MOSFET is based on a wide-bandgap semiconductor material.

26. The circuit of claim 24, wherein the MOSFET is controlled based on the first control signal.
